(19) United States
(12) Patent Application Publication
(10) Pub. No.: US 2025/0192430 A1
(43) Pub. Date: Jun. 12, 2025

(54) APPARATUS AND METHOD FOR HIGH FREQUENCY PHASE SHIFTER

(71) Applicant: ELECTRONICS AND TELECOMMUNICATIONS RESEARCH INSTITUTE, Daejeon (KR)

(72) Inventors: Seunghyun JANG, Daejeon (KR); Sunwoo Kong, Daejeon (KR); Bong Hyuk Park, Daejeon (KR); Seung Hun Wang, Daejeon (KR); Hui Dong Lee, Daejeon (KR); Jung Hwan Hwang, Daejeon (KR)

(21) Appl. No.: 18/975,869

(22) Filed: Dec. 10, 2024

(30) Foreign Application Priority Data
Dec. 12, 2023 (KR) 10-2023-0179733

(51) Int. Cl. H01Q 3/24; H04B 1/525; H04B 7/0426

(52) U.S. Cl. CPC H01Q 3/24; H04B 1/525; H04B 7/043

(57) ABSTRACT

Proposed are an apparatus and a method for a high frequency phase shifter. The apparatus of the phase shifter configured for a beamforming system includes a first path switch controlling an activation and a deactivation of a first path, a first path resonator having an impedance capable of realizing a parallel resonance with an impedance seen at both ends of the first path switch when the first path switch is in a control mode for the deactivation, a first inductor rendering an impedance seen from a connected terminal to exhibit an inductive characteristic, a second inductor rendering an impedance seen from a connected terminal to exhibit an inductive characteristic, and a path-based impedance converter converting an impedance thereof into an impedance generating a phase delay or into an impedance such that an impedance as large as possible is seen at both terminals of a second path.

### CROSS REFERENCE TO RELATED APPLICATION

The present application claims priority to Korean Patent Application No. 10-2023-0179733, filed Dec. 12, 2023, the entire contents of which are incorporated herein for all purposes by this reference.

### BACKGROUND

### Technical Field

The present disclosure generally relates to a phase shifter. More specifically, the present disclosure relates to an apparatus and a method for a high frequency phase shifter.

### Description of the Related Art

A beamforming system is a technology of forming a beam in a desired direction by using a plurality of antennas. The beamforming system controls a phase and an amplitude of each signal input into each antenna of an antenna array, thereby forming a direction and a shape of the beam.

A phase shifter structure for beam steering of the beamforming system is generally implemented by using a delay line and a switch.

### SUMMARY

On the basis of the discussion described above, the present disclosure proposes an apparatus and a method for a high frequency phase shifter.

In addition, in the present disclosure, there is provided an apparatus and a method for a high frequency phase shifter, the apparatus and the method being configured to minimize an insertion loss of the phase shifter in a beamforming system.

In addition, in the present disclosure, there is provided an apparatus and a method for a high frequency phase shifter, the apparatus and the method being capable of minimizing a power consumption of the phase shifter in the beamforming system and a required gain of an amplifier.

In addition, in the present disclosure, there is provided an apparatus and a method for a high frequency phase shifter, the apparatus and the method being configured such that a switch connected in series on a delay path in the phase shifter is minimized.

In order to achieve the above objectives, according to various aspects of the present disclosure, there is provided a first phase delay unit element of a phase shifter configured for a beamforming system, the first phase delay unit element including: a first switch configured to control an activation and a deactivation of a first path; a first path resonator having an impedance capable of realizing a parallel resonance with an impedance seen at both ends of the first switch when the first switch is in a control mode for the deactivation of the first path; a first inductor positioned on a second path and connected to an input terminal or an output terminal of a phase delay unit element, the first inductor being configured to render an impedance seen from a connected input terminal or a connected output terminal to exhibit an inductive characteristic; a second inductor positioned on the second path and connected to another input terminal or another output terminal of the phase delay unit element, the second inductor being configured to render an impedance seen from another connected input terminal or another connected output terminal to exhibit an inductive characteristic; and a path-based impedance converter positioned on the second path, the path-based impedance converter being configured to convert, according to an external control signal for selecting the first path or the second path, an impedance thereof into an impedance generating a phase delay on the second path by including the first inductor and the second inductor or into an impedance such that another impedance as large as possible is seen at both terminals of the second path by including the first inductor and the second inductor.

In order to achieve the above objectives, according to various aspects of the present disclosure, there is provided an operation method of a first phase delay unit element of a phase shifter configured for a beamforming system, the operation method including: controlling, by a first path switch, an activation and a deactivation of a first path; performing, by the first path resonator, a parallel resonance of an impedance seen at both ends of the first path switch when the first path switch is in a control mode for the deactivation of the first path; operating a first inductor such that the first inductor positioned on a second path and connected to an input terminal or an output terminal of a phase delay unit element renders an impedance seen from a connected terminal to exhibit an inductive characteristic; operating a second inductor such that the second inductor positioned on the second path and connected to another input terminal or another output terminal of the phase delay unit element renders an impedance seen from a connected terminal to exhibit an inductive characteristic; and operating a path-based impedance converter such that the path-based impedance converter to convert, according to an external control signal for selecting the first path or the second path, an impedance thereof into an impedance generating a phase delay on the second path including the first inductor and the second inductor or into an impedance such that an impedance as large as possible is seen at both terminals of the second path including the first inductor and the second inductor.

In the apparatus and method according to various aspects of the present disclosure, the insertion loss of the phase shifter in the beamforming system is minimized, so that the power consumption and the gain of the amplifier may be minimized.

In addition, in the apparatus and method according to various aspects of the present disclosure, the switch connected in series on the delay path in the phase shifter is minimized, so that a structure of the phase shifter is simplified and the phase shifter is capable of exhibiting the performance thereof stably.

The effects that can be obtained from the present disclosure are not limited to the above-mentioned effects, and other effects not mentioned herein will be clearly understood by those skilled in the art from the following description.

### BRIEF DESCRIPTION OF THE DRAWINGS

The above and other objectives, features, and other advantages of the present disclosure will be more clearly understood from the following detailed description when taken in conjunction with the accompanying drawings, in which:

FIG. 1A is a view illustrating a configuration of a beamforming system according to various embodiments of the present disclosure;

FIG. 1B is a view illustrating a circuit structure of a phase shifter according to various embodiments of the present disclosure;

FIG. 1C is a view illustrating a phase shifter circuit structure according to various embodiments of the present disclosure;

FIG. 2 is a view illustrating a three-stage phase shifter for beam steering of the beamforming system according to an embodiment of the present disclosure;

FIG. 3 is a view illustrating a situation in which a first path switch is configured as a Deep N-well NMOS element according to an embodiment of the present disclosure;

FIG. 4 is a view illustrating a variable impedance matching network configured as a delay capacitor connected in series with a path-based control switch according to an embodiment of the present disclosure;

FIG. 5 is a view illustrating an example of the phase shifter circuit structure according to an embodiment of the present disclosure;

FIG. 6 is a view illustrating an example of a configuration of a phase shifter layout according to an embodiment of the present disclosure;

FIG. 7A is a graph showing a simulation result of 4-bit phase shift characteristics according to an embodiment of the present disclosure;

FIG. 7B is a graph showing a simulation result of attenuation characteristics of phase shifters according to an embodiment of the present disclosure; and

FIG. 8 is a view illustrating an operation method of a first phase delay unit element of the phase shifter configured for the beamforming system according to an embodiment of the present disclosure.

### DETAILED DESCRIPTION

Terms used in the present disclosure are for the purpose of describing particular embodiments only and are not intended to limit other embodiments. A singular expression may include a plural expression unless there is a contextually distinctive difference. Unless otherwise defined, all terms including technical and scientific terms used herein have the same meaning as commonly understood by those ordinarily skilled in the art corresponding to the present disclosure. It will be further understood that terms, such as those defined in commonly used dictionaries, should be interpreted as having a meaning that is consistent with their meaning in the context of the relevant art, and will not be interpreted in an idealized or overly formal sense unless expressly so defined herein. Optionally, the terms defined in the present disclosure should not be interpreted to exclude the embodiments of the present disclosure.

A hardware-based approach is described for example in an embodiment of the present disclosure described hereinafter. However, since one or more embodiments of the present disclosure include a technique in which hardware and software are both used, a software-based approach is not excluded in the embodiments of the present disclosure.

In addition, in the detailed description and claims of the present disclosure, “at least one of A, B, and C” may mean “only A”, “only B”, “only C”, or “any combination of A, B, and C”. In addition, “at least one A, B, or C” or “at least one of A, B, and/or C” may mean “at least one of A, B, and C”.

Hereinafter, the present disclosure relates to an apparatus and a method for a high frequency phase shifter. Specifically, in the present disclosure, a method for a phase shifter circuit structure capable of minimizing an insertion loss of a phase shifter in a beamforming system so that a power consumption and a required gain of an amplifier are capable of being minimized.

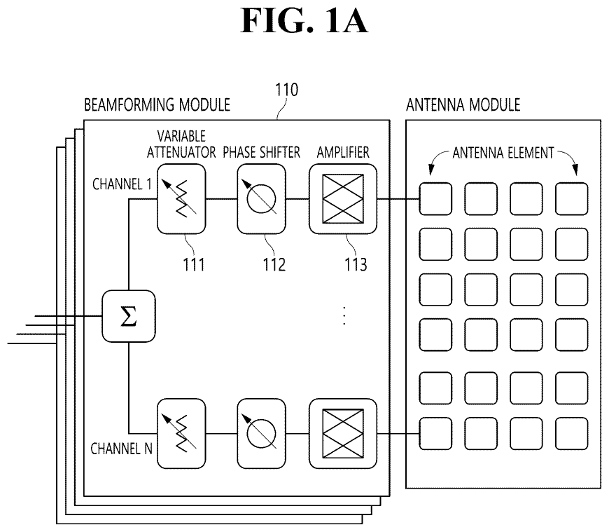

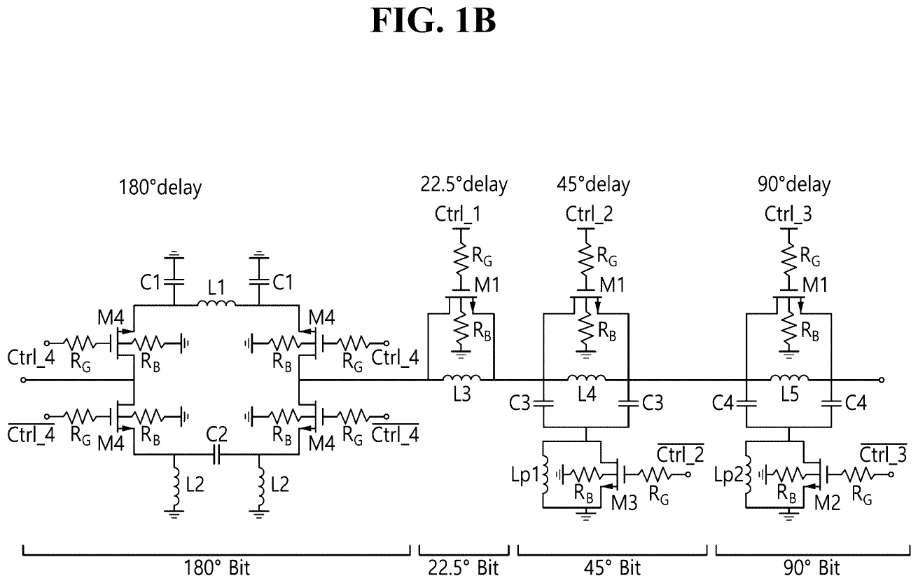

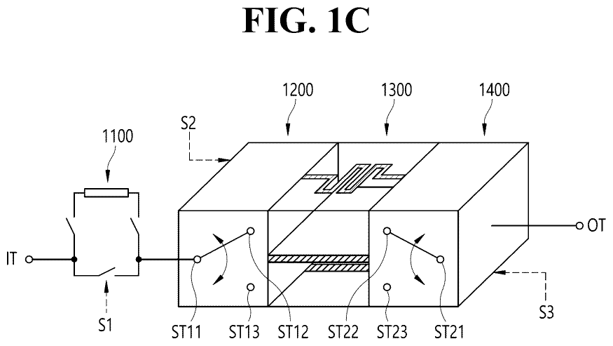

FIG. 1A is a view illustrating a configuration of a beamforming system according to various embodiments of the present disclosure.

Referring to FIG. 1A, a beamforming module 110 includes various components such as a variable attenuator 111, a phase shifter 112, and an amplifier 113.

The phase shifter 112 performs an important role in controlling a direction and a shape of a radio wave at an output of an antenna module by appropriately adjusting a signal phase of each channel of the beamforming module 110. For this reason, the phase shifter 112 is the most important component in terms of beam control.

However, the phase shifter 112 is a component that causes a loss in terms of signal magnitude, and one of the key performance characteristics of the phase shifter 112 of the present disclosure is minimizing the insertion loss as much as possible.

Particularly, for a high frequency band signal in which the beamforming system is widely applied, more gain is required in the amplifier 113 in order to compensate for insertion loss occurring in the phase shifter 112, which results in significantly higher power consumption compared to increasing a gain of a low frequency band signal amplifier.

In order to solve this problem, various previous studies have been conducted. In the previous paper (Low Insertion Loss, Compact 4-bit Phase Shifter in 65 nm CMOS for 5G applications, IEEE Microwave and Wireless Components Letters, pp. 37-39, January 2016), the study aimed to realize optimal insertion loss and minimum size by applying various phase shifter structures according to each phase value.

FIG. 1B is a view illustrating a circuit structure of a phase shifter according to various embodiments of the present disclosure. In FIG. 1B, a circuit structure of a phase shifter proposed in the previous paper (Low Insertion Loss, Compact 4-bit Phase Shifter in 65 nm CMOS for 5G applications, IEEE Microwave and Wireless Components Letters, pp. 37-39, January 2016) is exemplified, but the present disclosure is not limited thereto.

Referring to FIG. 1B, it can be seen that there are a total of four phase delay elements (a 180 degree phase delay element, a 90 degree phase delay element, a 45 degree phase delay element, and a 22.5 degree phase delay element), and all the remaining phase delay elements except for the 45 degree phase delay element and the 90 degree phase delay element have circuit structures different from each other.

Among the phase delay elements, the 22.5 degree phase delay element, the 45 degree phase delay element, and the 90 degree phase delay element do not have a switch connected in series on a path that generates a phase delay, the insertion loss is entirely determined by the delay elements.

However, the 180 degree phase delay element has a structure in which a signal must pass through a switch M4 twice regardless of whether any one path among a C1-L1-C1 path and a L2-C2-L2 path is selected, so that it can be confirmed that additional insertion loss occurs by the component other than the components that occurs the phase delay. According to the previous paper, the total insertion loss performance of a 4-bit phase shifter was 6.36 dB.

FIG. 1C is a view illustrating a phase shifter circuit structure according to various s embodiments of the present disclosure. In FIG. 1C, while a phase shifter of the related art (KR 10-2018-0059550) is exemplarily illustrated, it should not be construed as limiting the scope of the present disclosure.

Referring to FIG. 1C, in the related art, a first modification switched-type real-time delay phase shifter 1100, a first double-sided stacked-type delay phase shifter 1300, a first SPDT switch 1200, and a second SPDT switch 1400 are provided.

Furthermore, the primary characteristic of the related art is that an element constituting a phase delay path and an element constituting a through path are stacked through the double-sided stacked-type delay phase shifter 1300, thereby being capable of reducing the size of the phase shifter.

However, since the phase shifter in FIG. 1C includes a switch inside the first modification switched-type real-time delay phase shifter 1100, the insertion loss of the switch is reflected in the loss of the phase shifter, and a signal must pass through the first SPDT switch 1200 and the second SPDT switch 1400 in the phase shifter, so that there is a disadvantage that the phase shifter in FIG. 1C has a relatively high insertion loss.

Therefore, as described above, in order to optimize the power consumption of each channel in the beamforming module 110 and to minimize the required gain of the amplifier 113, a new phase shifter 112 circuit structure and a new apparatus for the new phase shifter 112 circuit structure that are capable of minimizing the insertion loss of the phase shifter 112 positioned in each channel.

The present disclosure relates to a phase shifter structure and an apparatus of the phase shifter structure for beam steering of a beamforming system. More specifically, the present disclosure relates to a phase shifter circuit structure capable of minimizing a power consumption and a required gain of an amplifier by minimizing an insertion loss of a phase shifter in the beamforming system, the phase shifter circuit structure having a simplified structure by minimizing a switch connected in series on a delay path inside the phase shifter, thereby being capable of realizing a stable performance.

In order to achieve the above objectives, a phase shifter for beam steering of a beamforming system according to the present disclosure may include: a first switch configured to control an activation and a deactivation of a first path; a first path resonator having an impedance capable of realizing a parallel resonance with an impedance seen at both ends of the first switch when the first switch is in a control mode for the deactivation of the first path; a first inductor positioned on a second path and connected to an input terminal or an output terminal of a phase delay unit element, the first inductor being configured to render an impedance seen from a connected terminal to exhibit an inductive characteristic; a second inductor positioned on the second path and connected to another input terminal or another output terminal of the phase delay unit element, the second inductor being configured to render an impedance seen from a connected terminal to exhibit an inductive characteristic; and a path-based impedance converter positioned on the second path, the path-based impedance converter being configured to convert, according to an external control signal for selecting the first path or the second path, an impedance thereof into an impedance generating a phase delay on the second path including the first inductor and the second inductor or into an impedance such that another impedance as large as possible is seen at both terminals of the second path including the first inductor and the second inductor.

Hereinafter, in the description of the present disclosure, a detailed description of the related known functions will be omitted if it is determined that the gist of the present disclosure may be unnecessarily blurred as it is obvious to those skilled in the art and some exemplary embodiments of the present disclosure will be described in detail with reference to exemplary drawings.

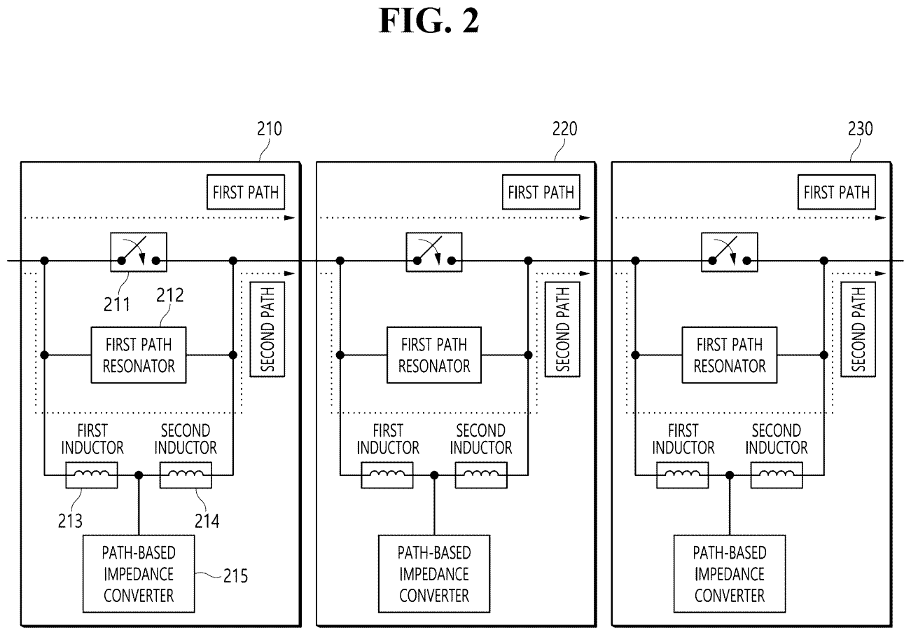

FIG. 2 is a view illustrating a three-stage phase shifter for beam steering of the beamforming system according to an embodiment of the present disclosure.

Referring to FIG. 2, a phase shifter may include: a first path switch 211 configured to control an activation and a deactivation of a first path; a first path resonator 212 having an impedance capable of realizing a parallel resonance with an impedance seen at both ends of the first path switch when the first path switch is in a control mode for the deactivation of the first path; a first inductor 213 positioned on a second path and connected to an input terminal or an output terminal of a phase delay unit element, the first inductor being configured to render an impedance seen from a connected terminal to exhibit an inductive characteristic; a second inductor 214 positioned on the second path and connected to another input terminal or another output terminal of the phase delay unit element, the second inductor being configured to render an impedance seen from a connected terminal to exhibit an inductive characteristic; and a path-based impedance converter 215 positioned on the second path, the path-based impedance converter being configured to convert, according to an external control signal for selecting the first path or the second path, an impedance thereof into an impedance generating a phase delay on the second path including the first inductor and the second inductor or into an impedance such that another impedance as large as possible is seen at both terminals of the second path including the first inductor and the second inductor.

A circuit operation method of the phase shifter for the beamforming system configured as illustrated in FIG. 2 is described as follows.

(1) In a first phase delay unit element 210, when the first phase delay unit element 210 is controlled such that a signal is transmitted to the first path, the first path switch 211 is turned on so that most of the signal is capable of being transmitted through the first path via the first path switch 211. Since a turn-on resistance of the first path switch 211 primarily affects the signal passing through the first path, the signal may be output with relatively low delay.

At this time, in order to minimize a signal leakage from both terminals of the first path switch 211 toward the second path, the first path resonator 212 is required to exhibit a sufficiently large impedance in a frequency band of the transmitted signal. Furthermore, the impedance of the path-based impedance converter 215 may be controlled such that another impedance as large as possible is seen at the both terminals of the second path in the frequency band of the transmitted signal, the second path including the first inductor and the second inductor.

(2) When the first phase delay unit element 210 is controlled such that a signal is transmitted to the second path, the first path switch 211 is turned off so that most of the signal is capable of being transmitted through the second path via the first inductor 213 and the second inductor 214. The impedance of the path-based impedance converter 215 may be converted into an impedance which minimizes reflection waves as much as possible at the input terminal and the output terminal of the first phase delay unit element 210 including the first inductor and the second inductor and which realizes a desired phase delay characteristic. Therefore, the signal at the output terminal after passing through the second path may be output after undergoing greater phase delay compared to the signal at the input terminal.

At this time, in order to minimize the signal leakage from the both terminals of the second path to the first path switch 211 that is turned off, the first path resonator 212 may be controlled such that a sufficiently large impedance is realized by tuning a resonant frequency to be similar to the frequency band of the transmitted signal in consideration of the impedance of the first path switch 211 which is in the turned-off state and which is connected in parallel.

According to an embodiment, each of the phase delay unit elements 210, 220, and 230 is an independent phase delay element, and may have phase delay characteristics different from each other.

According to an embodiment, since each of the phase delay unit elements 210, 220, and 230 is the independent phase delay element, the phase shifter 112 may be configured in conjunction with phase delay elements having structures different from each other.

According to an embodiment, the first path switch 211 may be configured as an NMOS or a PMOS of a complementary metal-oxide-semiconductor (CMOS) semiconductor process.

According to an embodiment, the first path resonator 212 may be configured as an inductor.

According to an embodiment, the path-based impedance converter 215 may utilize a varactor in which a capacitance thereof is changed by an external control signal.

According to an embodiment, the first path switch 211 may not a single switch but may be configured as a combination of a plurality of sub-switches 221.

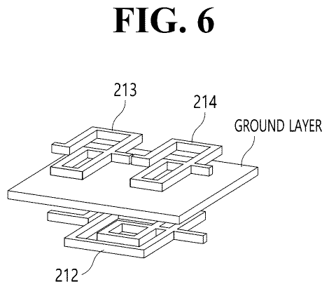

According to an embodiment, the first path resonator 212 is not an element through which a signal passes, but is an element that minimizes leakage of a signal to the first path when the signal passes through the second path, so that a quality factor of the first path resonator 212 does not have to be good. Therefore, the first path resonator 212 may be realized by using a thin metal layer having a relatively low thickness in the semiconductor process. Therefore, as illustrated in FIG. 6, the first path resonator may be realized by using a low metal layer and sharing a middle ground layer with the first inductor 213 or the second inductor 214.

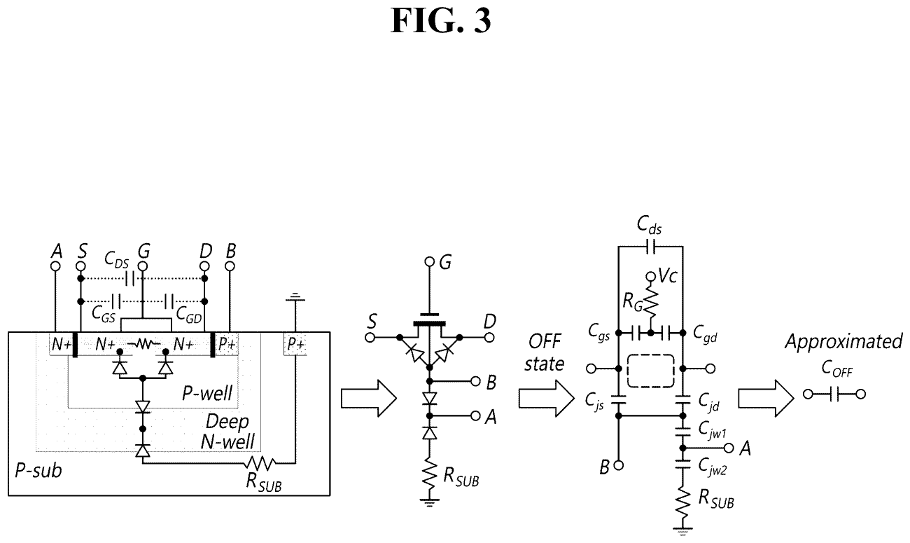

FIG. 3 is a view illustrating a situation in which the first path switch is configured as a Deep N-well NMOS element according to an embodiment of the present disclosure.

Referring to FIG. 3, when the first path switch 211 in FIG. 2 is configured as a Deep N-well NMOS element as illustrated in FIG. 3, the first path switch 211 may be approximated to a series capacitor C_{off} when an NMOS switch is turned off. Furthermore, an inductor constituting the first path resonator 212 and including the C_{off} of the NMOS switch may have an inductance capable of realizing a parallel resonance.

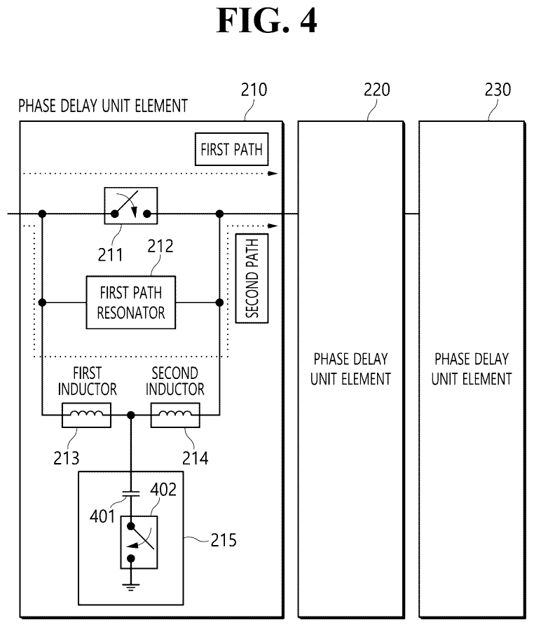

FIG. 4 is a view illustrating a variable impedance matching network configured as a delay capacitor connected in series with a path-based control switch according to an embodiment of the present disclosure. Referring to FIG. 4, the path-based impedance converter 215 illustrated in FIG. 2 may be configured as a variable impedance matching network including a path-based control switch 402 and a delay capacitor 401 connected in series with the path-based control switch 402 so that the path-based impedance converter 215 has a characteristic that a capacitance of the path-based impedance converter 215 is changed by an external control signal for selecting the first path or second path.

According to an embodiment, the delay capacitor 401 may have a capacitance value that causes a specific phase delay by being in conjunction with the first inductor 213 and the second inductor 214.

According to an embodiment, the first path switch 211 may not be a single switch but may be configured as a combination of the plurality of sub-switches 221.

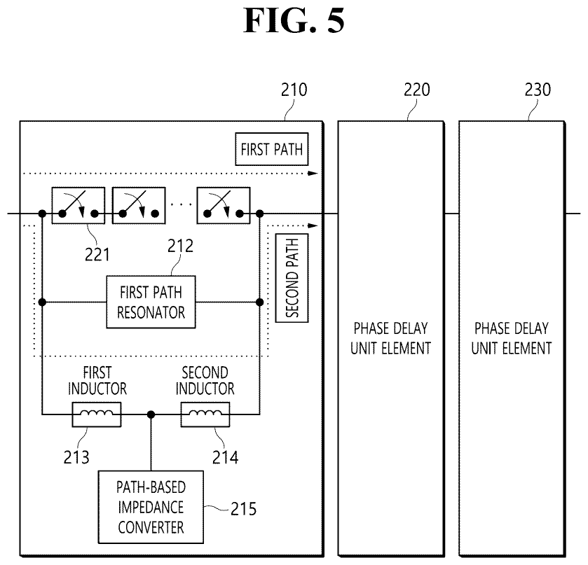

FIG. 5 is a view illustrating an example of a phase shifter circuit structure according to an embodiment of the present disclosure.

Referring to FIG. 5, the combination of the sub-switches 221 may be configured such that the total insertion loss of the combination of the sub-switches 221 is similar to the insertion loss that the signal undergoes in the second path. As such, the insertion loss of the first path and the insertion loss of the second path become similar to each other, so that the difference in signal magnitude according to the path selection may be minimized.

According to an embodiment, the first path resonator 212 is not an element through which a signal passes, but is an element that minimizes leakage of a signal to the first path when the signal passes through the second path, so that a quality factor of the first path resonator 212 does not have to be good. Therefore, the first path resonator 212 may be realized by using a thin metal layer having a relatively low thickness in the semiconductor process. Therefore, as illustrated in FIG. 6, the first path resonator may be realized by using a low metal layer while the first path resonator shares a ground layer at the center with the first inductor 213 or the second inductor 214.

FIG. 6 is a view illustrating an example of a configuration of a phase shifter layout according to an embodiment of the present disclosure.

Referring to FIG. 6, the first path resonator 212 may be configured in a form in which a plurality of metal layers is connected in parallel by vias, and may be realized as a substantially thick metal layer.

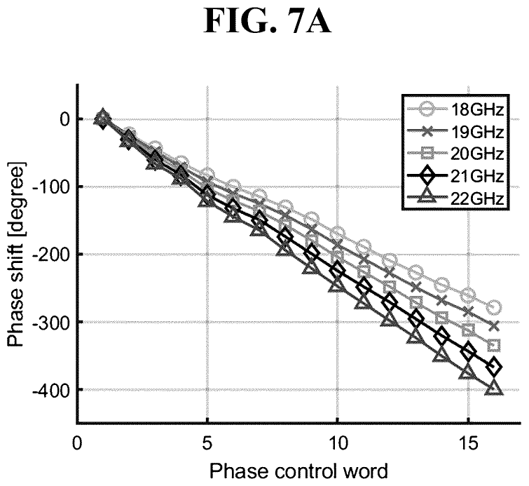

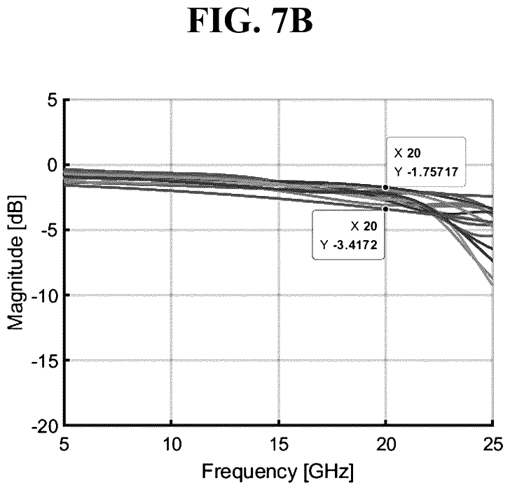

FIG. 7A is a graph showing a simulation result of 4-bit phase shift characteristics according to an embodiment of the present disclosure.

In FIG. 7A, a 4-bit phase shifter circuit for a K-band (18 GHz-27 GHz) formed of a 180 degree phase shifting unit element, a 90 degree phase shifting unit element, a 45 degree phase shifting unit element, and a 22.5 degree phase shifting unit element according to the present disclosure is designed by using a CMOS 65 nm Process Design Kit (PDK). In order to compare the phase shifter performance, a 4-bit phase shifter unit (formed of the 180 degree phase shifting unit element, the 90 degree phase shifting unit element, the 45 degree phase shifting unit element, and the 22.5 degree phase shifting unit element) having the same configuration as the previous paper (Low Insertion Loss, Compact 4-bit Phase Shifter in 65 nm CMOS for 5G applications, IEEE Microwave and Wireless Components Letters, pp. 37-39, January 2016) was formed.

The simulation result for each frequency for the phase shifting performance of the designed phase shifter is illustrated in FIG. 7A. Looking at the simulation result, it can be seen that a total of 360 degrees of phase shifting range is capable of being provided from about the 20 GHz band.

FIG. 7B is a graph showing a simulation result of attenuation characteristics of phase shifters according to an embodiment of the present disclosure

In the phase shifter, not only the phase shifting performance but also the attenuation characteristics of the phase shifter in all phase shifting combinations are very important performance indicators.

In order to check the indicators, the simulation result of the attenuation characteristics of all phase shifting combinations of the designed phase shifter is illustrated in FIG. 7B. According to the simulation result, the reduction characteristics of about −1.76 dB to −3.4 dB at a frequency of 20 GHz were shown, and an average attenuation was about 2.5 dB. Even considering that it is the simulation result, it can be seen that the simulation result shows sufficiently superior performance compared to the average attenuation value of 6.36 dB in the previous paper.

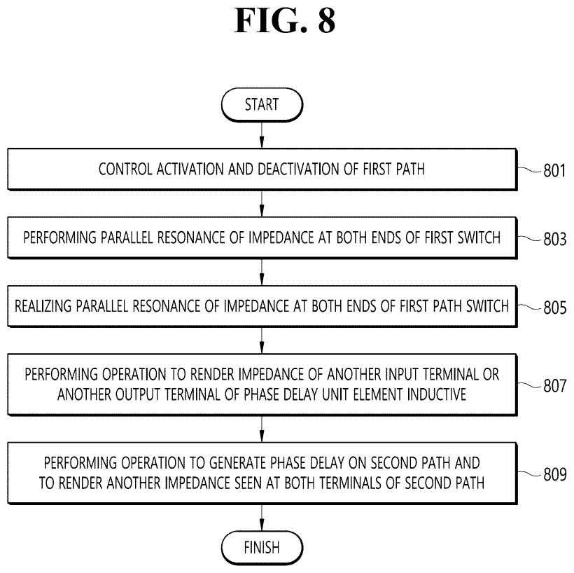

FIG. 8 is a view illustrating an operation method of a first phase delay unit element of the phase shifter configured for the beamforming system according to an embodiment of the present disclosure. Operations illustrated in FIG. 8 is not constrained by the order, and each operation may be operated in a different sequential relationship, or may be operated simultaneously.

Referring to FIG. 8, the first phase delay unit element may control the activation and the deactivation of the first path by using the first path switch (801).

The first phase delay unit element may realize the parallel resonance of the impedance seen at the both ends of the first path switch by using the first path resonator when the first switch is in the control mode for the deactivation of the fist path (803).

By using the first inductor positioned on the second path and connected to the input terminal or the output terminal of the phase delay unit element, the first phase delay unit element may be operated such that the impedance seen from the connected input terminal or the connected output terminal exhibits an inductive characteristic (805).

By using the second inductor positioned on the second path and connected to another input terminal or another output terminal of the phase delay unit element, the first phase delay unit element may be operated such that the impedance seen from another connected input terminal or another connected output terminal exhibits an inductive characteristic (807).

By using the path-based impedance converter positioned on the second path, the first phase delay unit element may be operated such that the impedance of the path-based impedance converter is converted into an impedance generating a phase delay on the second path including the first inductor and the second inductor or into an impedance such that another impedance as large as possible is seen at the both terminals of the second path including the first inductor and the second inductor (809).

According to an embodiment, the first phase delay unit element may control the first path switch such that the first path switch is turned on so that the signal is transmitted to the first path.

According to an embodiment, in order for the signal to be transmitted to the second path, the first phase delay unit element may control the first path switch such that the first path switch is turned off so that the signal is capable of passing through the second path via the first inductor and the second inductor.

According to an embodiment, the path-based impedance converter may have the impedance that realizes a specific phase delay on the second path in the frequency band of the transmitted signal, the second path including the first inductor and the second inductor.

According to an embodiment, in order to minimize the leakage of the signal from the both terminals of the second path to the first path switch that is turned off, the first phase delay unit element may be operated such that the first path resonator has the impedance that is capable of realizing the parallel resonance of the impedance of the first path switch which is in the turn-off state and which is connected in parallel.

According to an embodiment, the first phase delay unit element may constitute the phase shifter by being connected to a second phase delay unit element and a third phase delay unit element.

According to an embodiment, the second phase delay unit element and the third phase delay unit element may have the same structure as the first phase delay unit element, but may have parameter values different from that of the first phase delay unit element.

According to an embodiment, the first path switch may be configured as at least one of an NMOS or a PMOS of a complementary metal-oxide-semiconductor (CMOS) semiconductor process.

According to an embodiment, the first path resonator may be configured as an inductor.

According to an embodiment, the path-based impedance converter may utilize a varactor in which a capacitance thereof is changed by an external control signal.

According to an embodiment, the path-based impedance converter may include a path-based control switch and a delay capacitor connected in series with the path-based control switch.

According to an embodiment, the delay capacitor may have a capacitance value that causes a specific phase delay by being in conjunction with the first inductor and the second inductor.

According to an embodiment, the first path switch may include a combination of a plurality of sub-switches.

According to an embodiment, the insertion loss of the plurality of sub-switches may be determined on the basis of the insertion loss corresponding to the second path.

According to an embodiment, the first path resonator is not an element through which a signal passes, and may minimize leakage of a signal to the first path when the signal passes through the second path.

According to an embodiment, the first path resonator may be realized by sharing the ground layer between the first inductor and the second inductor.

According to an embodiment, the first path resonator may be configured in a form in which a plurality of metal layers is connected in parallel to each other by vias.

The specific embodiment of the present disclosure is described in detail above. However, the present disclosure is not limited to the specific embodiment. It would be apparent to a person of ordinary skill in the art that various modifications to the present disclosure are possible within the scope of the technical idea of the present disclosure.

The methods according to the embodiments of the present disclosure as described herein or in the following claims may be implemented as hardware, software, or a combination of hardware and software.

When the methods are implemented as software, a computer-readable storage medium storing one or more programs (for example, software modules) may be provided. The one or more programs stored in the computer-readable storage medium are configured for execution by one or more processors in an electronic device. The one or more programs include instructions directing the electronic device to execute the methods according to the embodiments of the present disclosure as described herein or in the following claims.

The programs (for example, software modules or software) may be stored in a non-volatile memory including a random access memory (RAM) or a flash memory, a read only memory (ROM), an electrically erasable programmable read only memory (EEPROM), a magnetic disc storage device, a compact disc-ROM (CD-ROM), a digital versatile disc (DVD), another optical storage device, or a magnetic cassette. Alternatively, the programs may be stored in a memory including a combination of some or all of the above-mentioned storage media. In addition, a plurality of such memories may be included.

In addition, the programs may be stored in an attachable storage device accessible through any or a combination of communication networks such as the Internet, an intranet, a local area network (LAN), a wide area network (WAN), and a storage area network (SAN). Such a storage device may access, via an external port, the electronic device that performs embodiments of the present disclosure. Furthermore, an additional storage device on the communication network may access the electronic device that performs embodiments of the present disclosure.

In the afore-described embodiments of the present disclosure, an element or elements included in the present disclosure are expressed in a singular or plural form according to the described embodiments of the present disclosure. However, the singular or plural form is selected appropriately for a situation assumed for convenience of description, the present disclosure is not limited to the singular or plural form, and an element expressed in a singular form may include a plurality of elements and elements expressed in a plural form may include a single element.

Specific embodiments of the present disclosure are described in the description of the present disclosure, but it will be understood that various modifications may be made without departing the scope of the present disclosure. Thus, the scope of the present disclosure is not limited to the embodiments described herein and should be defined by the appended claims and their equivalents.

What is claimed is:

1. An apparatus as a first phase delay unit element of a phase shifter configured for a beamforming system, the apparatus comprising:
a first path switch configured to control an activation and a deactivation of a first path;
a first path resonator having an impedance capable of realizing a parallel resonance with an impedance seen at both ends of the first path switch when the first path switch is in a control mode for the deactivation of the first path;
a first inductor positioned on a second path and connected to an input terminal or an output terminal of a phase delay unit element, the first inductor being configured to render an impedance seen from a connected terminal to exhibit an inductive characteristic;
a second inductor positioned on the second path and connected to another input terminal or another output terminal of the phase delay unit element, the second inductor being configured to render an impedance seen from a connected terminal to exhibit an inductive characteristic; and
a path-based impedance converter positioned on the second path, the path-based impedance converter being configured to convert, according to an external control signal for selecting the first path or the second path, an impedance thereof into an impedance generating a phase delay on the second path including the first inductor and the second inductor or into an impedance such that an impedance as large as possible is seen at both terminals of the second path including the first inductor and the second inductor.

2. The apparatus of claim 1, wherein the first path switch is configured to be controlled such that the first path switch is turned on so that a signal is transmitted to the first path.

3. The apparatus of claim 1, wherein the first path switch is configured to be controlled such that the first path switch is turned off so that a signal is transmitted to the second path, so that the signal passes through the second path via the first inductor and the second inductor.

4. The apparatus of claim 3, wherein the path-based impedance converter has an impedance that realizes a specific phase delay on the second path in the frequency band of the signal that is transmitted, the second path including the first inductor and the second inductor.

5. The apparatus of claim 4, wherein, in order to minimize a signal leakage from the both terminals of the second path to the first path switch, the first path resonator has an impedance capable of realizing a parallel resonance of an impedance of the first path switch which is connected in parallel with the first path resonator and which is turned off.

6. The apparatus of claim 1, a second phase delay unit element and a third phase delay unit element have the same structure as the first phase delay unit element but have different parameter values, and
the phase shifter is formed by combining the first phase delay unit element, the second phase delay unit element, and the third phase delay unit element.

7. The apparatus of claim 1, wherein the first path switch comprises at least one of an NMOS or a PMOS of a complementary metal-oxide-semiconductor (CMOS) semiconductor process.

8. The apparatus of claim 1, wherein the first path resonator is configured as an inductor.

9. The apparatus of claim 1, wherein the path-based impedance converter utilizes a varactor in which a capacitance thereof is changed by the external control signal.

10. The apparatus of claim 9, wherein the path-based impedance converter comprises a path-based control switch and a delay capacitor that is connected in series with the path-based control switch.

11. The apparatus of claim 10, wherein the delay capacitor has a capacitance value that causes a specific phase delay by being in conjunction with the first inductor and the second inductor.

12. The apparatus of claim 1, wherein the first path switch comprises a combination of a plurality of sub-switches.

13. The apparatus of claim 12, wherein an insertion loss of the plurality of sub-switches is determined on the basis of an insertion loss corresponding to the second path.

14. The apparatus of claim 1, wherein the first path resonator is not an element through which a signal passes, and is configured to minimize a signal leakage toward the first path while a signal passes through the second path.

15. The apparatus of claim 1, wherein the first path resonator is configured by sharing a ground layer between the first inductor and the second inductor.

16. The apparatus of claim 1, wherein the first path resonator is configured in a form in which a plurality of metal layers is connected in parallel to each other with vias.

17. An operation method of a first phase delay unit element of a phase shifter configured for a beamforming system, the operation method comprising:
controlling, by a first path switch, an activation and a deactivation of a first path;
performing, by the first path resonator, a parallel resonance of an impedance seen at both ends of the first path switch when the first path switch is in a control mode for the deactivation of the first path;
operating a first inductor such that the first inductor positioned on a second path and connected to an input terminal or an output terminal of a phase delay unit element renders an impedance seen from a connected terminal to exhibit an inductive characteristic;
operating a second inductor such that the second inductor positioned on the second path and connected to another input terminal or another output terminal of the phase delay unit element renders an impedance seen from a connected terminal to exhibit an inductive characteristic; and
operating a path-based impedance converter such that the path-based impedance converter to convert, according to an external control signal for selecting the first path or the second path, an impedance thereof into an impedance generating a phase delay on the second path including the first inductor and the second inductor or into an impedance such that an impedance as large as possible is seen at both terminals of the second path including the first inductor and the second inductor.

18. The operation method of claim 17, wherein the first path switch is configured to be controlled such that the first path switch is turned on so that a signal is transmitted to the first path.

19. The operation method of claim 17, wherein the first path switch is configured to be controlled such that the first path switch is turned off so that a signal is transmitted to the second path, so that the signal passes through the second path via the first inductor and the second inductor.

20. The operation method of claim 19, wherein the path-based impedance converter has an impedance that realizes a specific phase delay on the second path in the frequency band of the signal that is transmitted, the second path including the first inductor and the second inductor.
